(19) United States
(12) Patent Application Publication
(10) Pub. No.: US 2013/0264303 A1
(43) Pub. Date: Oct. 10, 2013

(54) METHOD FOR THE PLASMA TREATMENT OF WORKPIECES AND WORKPIECE COMPRISING A GAS BARRIER LAYER

(71) Applicants: Arne Andersen, Hamburg (DE); Michael Herbort, Hamburg (DE); Sonke Siebels, Hamburg (DE)

(72) Inventors: Arne Andersen, Hamburg (DE); Michael Herbort, Hamburg (DE); Sonke Siebels, Hamburg (DE)

(73) Assignee: KHS CORPOPLAST GMBH, Hamburg (DE)

(21) Appl. No.: 13/993,778

(22) PCT Filed: Dec. 15, 2011
(86) PCT No.: PCT/DE2011/002159

§ 371 Date: Jun. 13, 2013

(30) Foreign Application Priority Data
Dec. 15, 2010 (DE) 102010055155.4

(51) Int. Cl. C23C 16/511

(52) U.S. Cl. CPC C23C 16/511
USPC 215/12.1; 427/575; 428/448

(57) ABSTRACT

The method serves for the plasma treatment of workpieces. The workpiece is inserted into a chamber of a treatment station that can be at least partially evacuated. The plasma chamber is bounded by a chamber bottom, a chamber top and a lateral chamber wall. The plasma treatment involves depositing a coating on the workpiece. The ignition of the plasma is performed by microwave energy. The coating consists at least of a gas barrier layer and a protective layer. The gas barrier layer contains SiOx and the protective layer contains carbon. The protective is produced from a gas that contains at least a silicon compound and argon.

The invention relates to a method for the plasma treatment of workpieces, in which the workpiece is inserted into a plasma chamber and in which subsequently a coating is deposited on the workpiece under the action of a negative pressure after igniting a plasma, and in which the plasma is ignited by way of microwave energy, wherein the coating includes at least a gas barrier layer and a protective layer.

The invention further relates to a workpiece made of a thermoplastic material, which in the region of at least one surface is provided with a gas barrier layer that is deposited from plasma and includes SiOx, a protective layer comprising carbon being disposed on the gas barrier layer.

Such methods are used to provide plastic materials with surface coatings, for example. In addition, such devices are already known for coating the inner or outer surfaces of containers that are intended for the packaging of liquids. Moreover, devices for plasma sterilization are known.

PCT WO 95/22413 describes a plasma chamber for coating the insides of bottles made of PET. The bottles to be coated are pushed into a plasma chamber by a movable bottom and connected to an adapter in the region of a bottle opening. The interior of the bottle can be evacuated through the adapter. In addition, a hollow gas lance is introduced through the adapter into the interior space of the bottle so as to supply process gas. The plasma is ignited using microwave.

It is also already known from this publication to dispose a plurality of plasma chambers on a rotating wheel. This supports a high production rate of bottles per unit of time.

The unexamined patent application EP 10 10 773 describes a feed device so as to evacuate an interior space of a bottle and supply the same with process gas. PCT WO 01/31680 describes a plasma chamber into which the bottles are introduced by a movable cover, which was previously connected to an opening region of the bottles.

PCT WO 00/58631 likewise already shows the arrangement of plasma stations on a rotating wheel and for such an arrangement describes an association of vacuum pumps and plasma stations in a grouped manner, so as to support the advantageous evacuation of the chambers and the interior spaces of the bottles. In addition, the coating of multiple containers in a common plasma station or a common cavity is mentioned.

Another arrangement for carrying out an interior coating process of bottles is described in PCT WO 99/17334. This document describes in particular an arrangement of a microwave generator above the plasma chamber and a vacuum and working fluid feed line through the bottom of the plasma chamber.

DE 10 2004 020 185 A1 already describes a gas lance, which can be introduced into the interior space of a preform to be coated and is used to feed process gases. The gas lance can be positioned in the longitudinal direction of the container.

In the predominant number of known devices, container layers that are generated by the plasma and made of silicon oxides having the general chemical formula SiOx are used to improve barrier properties of the thermoplastic material. Such barrier layers prevent oxygen from penetrating into the packaged liquids and prevent carbon dioxide from exiting CO₂-containing liquids.

WO 03/014412 A2 describes the execution of a plasma coating method, in which the necessary energy input takes place by way of pulsed microwave energy. A suitable pulse width and pulse level for the microwave energy are selected for carrying out the entire coating process. In addition, pauses between the individual pulses are established and kept constant for the duration of the coating. According to this prior art, the volume flow of processes gases that are supplied and the mixture of process gases are varied when carrying out the coating process. The mixing ratios and/or the respective volume flows of the process gases are typically changed at particular times so as to achieve a multi-layer composition. When barrier layers made of SiOx are applied to a substrate made of plastic material, typically two layers are generated, which is to say an adhesive layer and the actual barrier layer. Depending on the application, an additional protective layer can be disposed on the barrier layer.

The process gases that are used typically include HMDSO or HMDSN, for example, so as to provide the silicon and oxygen as the oxidizing gas. The properties of the respective deposited layer, and in particular the carbon content, are controlled by the amount of oxygen that is supplied and/or the manner in which the microwave energy is applied.

The existing methods are not yet able to meet all the requirements in terms of the applied protective layers. For example, it is not entirely possible to eliminate the possibility for undesirable substances that change the flavor to be given off into the bottled product, and additionally the requirements in regard to the protective layer are constantly increasing in terms of resistance, especially the requirements in terms of the resistance to pH values in the alkaline range.

It is therefore the object of the present invention to improve a method of the type mentioned above in such a way that the properties of the protective layer are improved.

This object is achieved according to the invention by creating the protective layer from a gas that includes at least one silicon compound and argon.

Another object of the present invention is to provide a workpiece of the type mentioned above in such a way that the protective layer has improved properties.

This object is achieved according to the invention in that the protective layer includes argon.

The use of argon as a process gas when creating the protective layer prevents the generation of substances that are noticeable in terms of taste. In addition, it is considered in particular to substitute the use of oxygen or at least reduce the amount of oxygen during the creation of the protective layer by the argon. It has been shown that the protective layer is improved over the prior art both with regard to the resistance thereof to outside influences and with regard to further properties.

According to a typical process variant, the use of HMDSO is considered as a process gas. According to another process variant, it is also possible to use HMDSN as a process gas. Controllability of the process is supported by using pulsed microwave for igniting the plasma.

A simple process can be achieved by supplying the process gases in a substantially constant volume flow over the duration of the creation of the protective layer.

Particularly advantageous properties can be achieved by depositing carbon in a content of approximately 30 to 60 element percent in the protective layer.

The method according to the invention is especially suitable for influencing the course of a coating method for bottles made of plastic material. Here, especially the insides of these bottles are coated with a layer made of SiOx, wherein the adhesion of the layer made of SiOx on the plastic material can be improved by an intermediate layer, which is designed as an adhesion promoter. The coating method is preferably carried out as a plasma impulse chemical vapor deposition (PICVD) plasma process. In such a method, the plasma is ignited using pulsed microwaves. The pulses can be controlled with regard to the pulse widths, pulse spacings and pulse levels thereof.

Exemplary embodiments of the invention are shown schematically in the drawings. In the drawings:

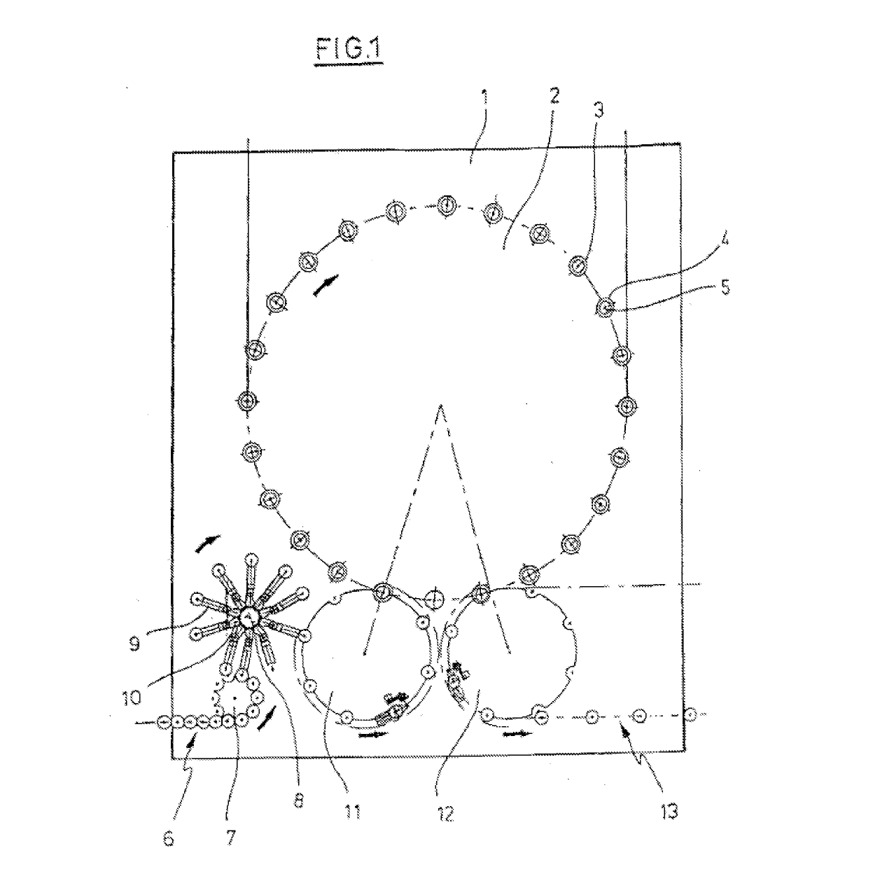

FIG. 1 is a schematic diagram of a plurality of plasma chambers, which are disposed on a rotating plasma wheel and in which the plasma wheel is coupled to input and output wheels;

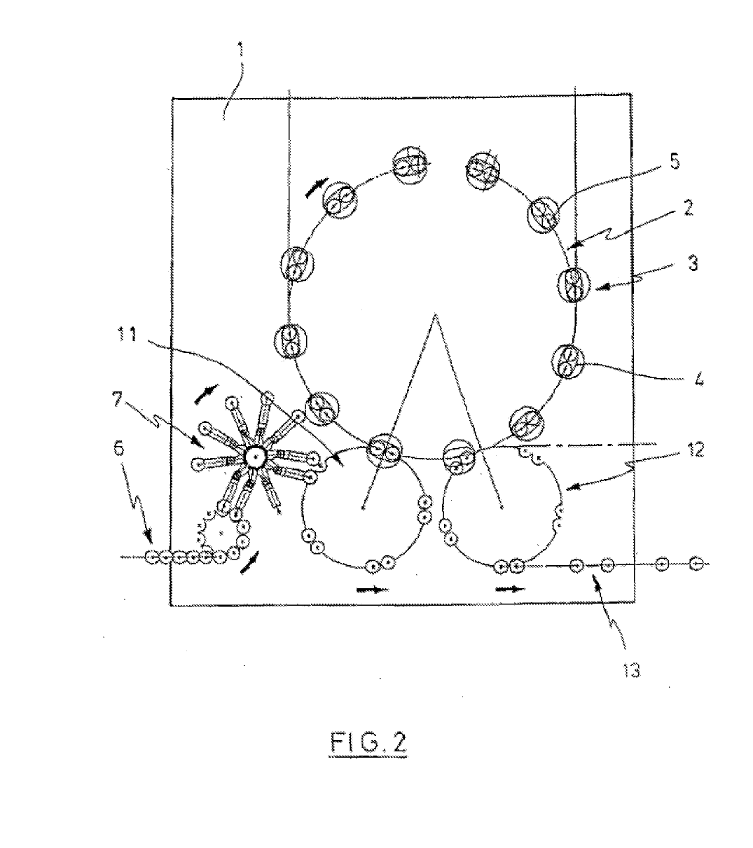

FIG. 2 shows an arrangement similar to FIG. 1, in which the plasma stations are equipped with two plasma chambers, respectively;

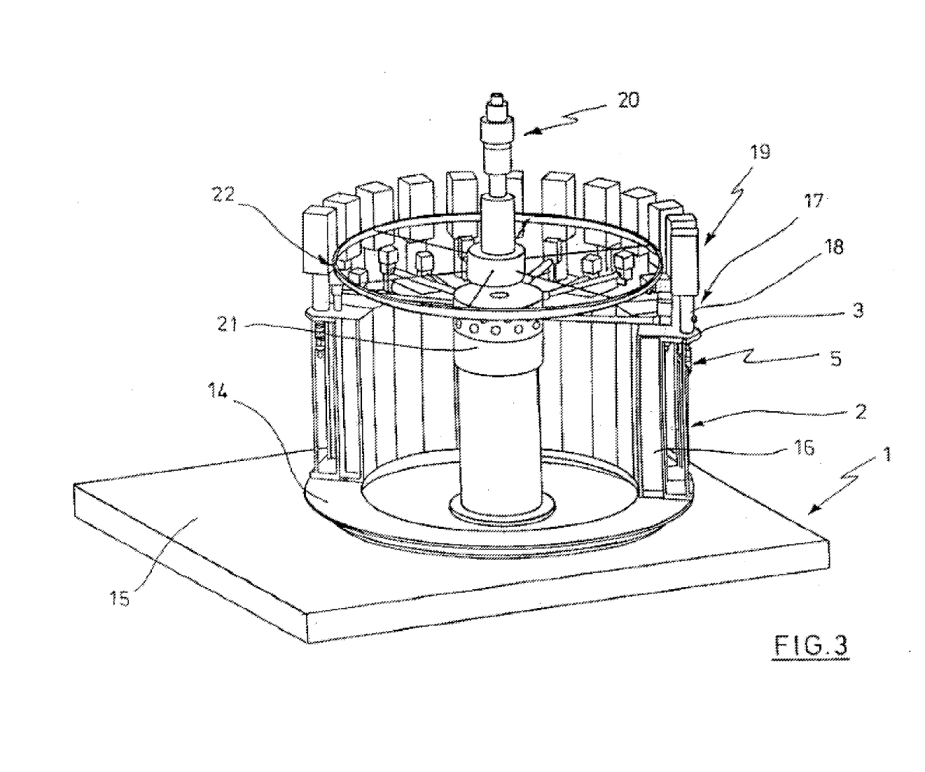

FIG. 3 is a perspective illustration of a plasma wheel comprising a plurality of plasma chambers;

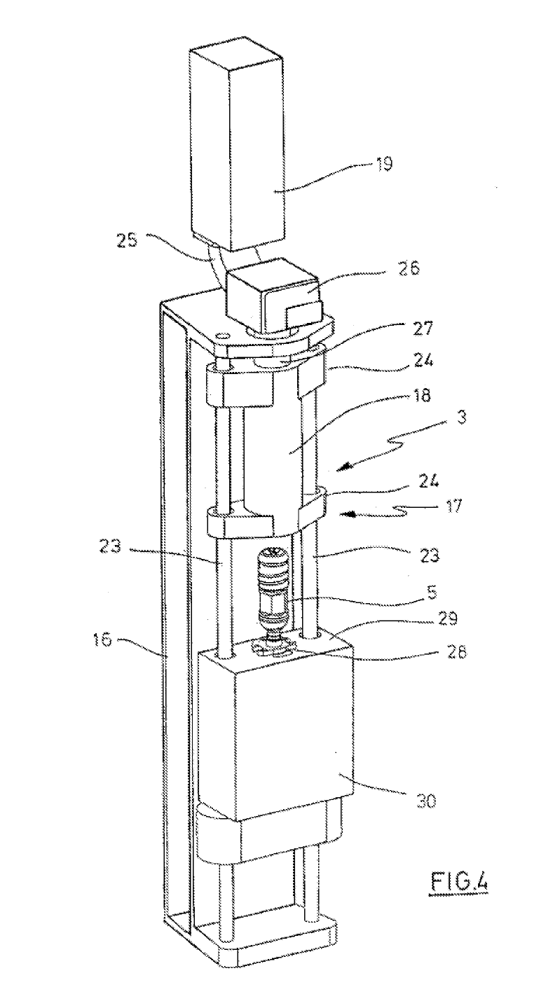

FIG. 4 is a perspective illustration of a plasma station comprising a cavity;

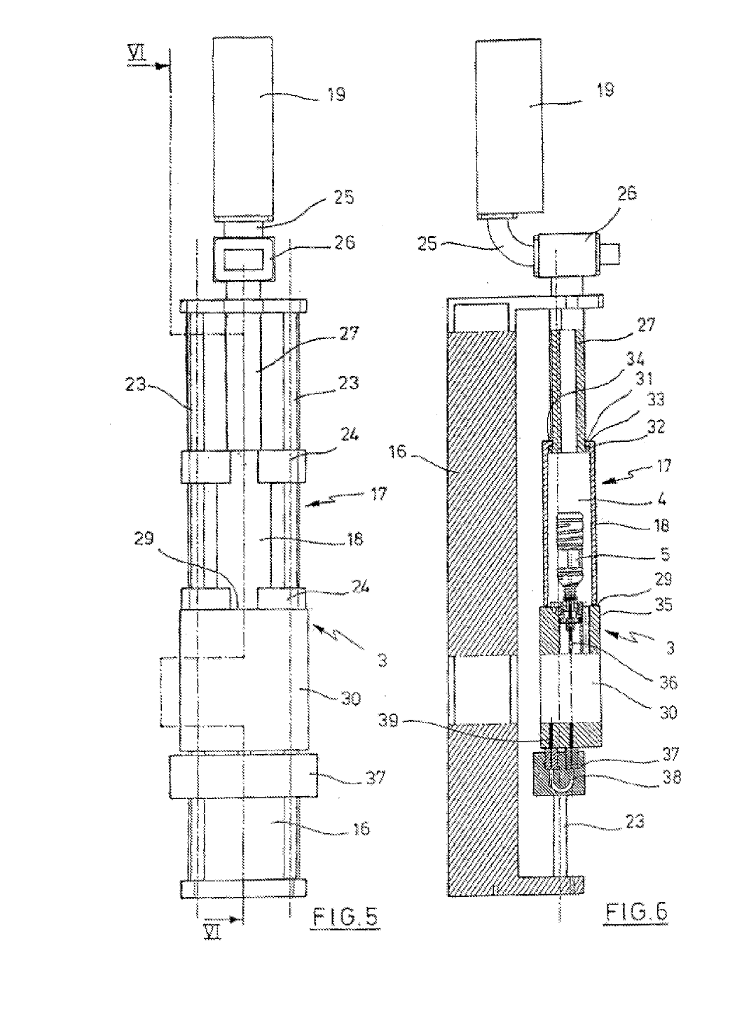

FIG. 5 is a front view of the device according to FIG. 4 with a closed plasma chamber;

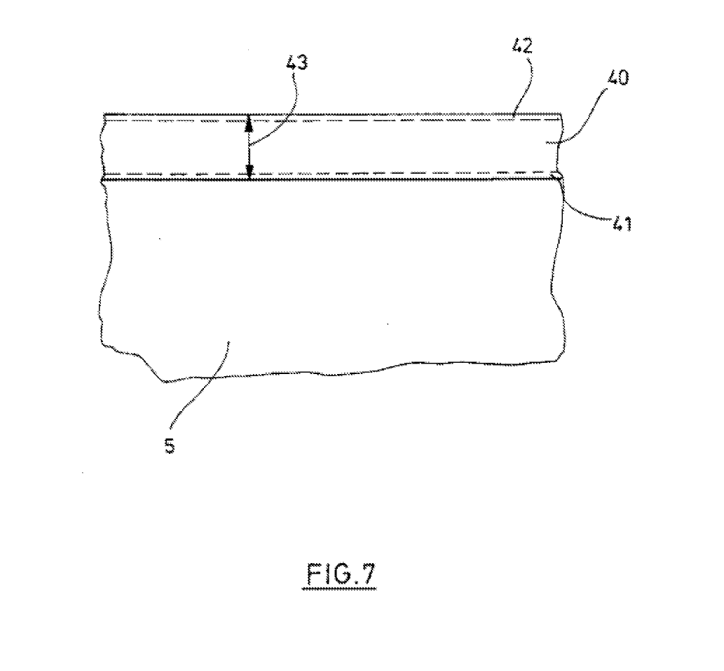

FIG. 6 is a cross-sectional view along intersecting line VI-VI in FIG. 5;

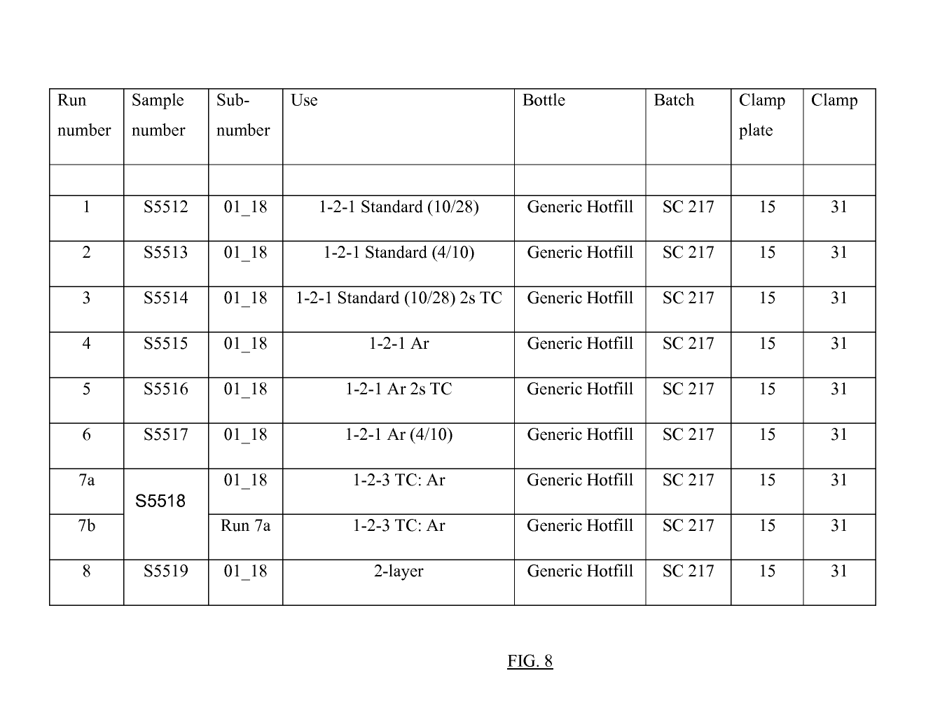

FIG. 7 is a partial representation of a cross-section through a substrate comprising a barrier layer;

FIG. 8 is a first table to illustrate different variants for carrying out the coating process;

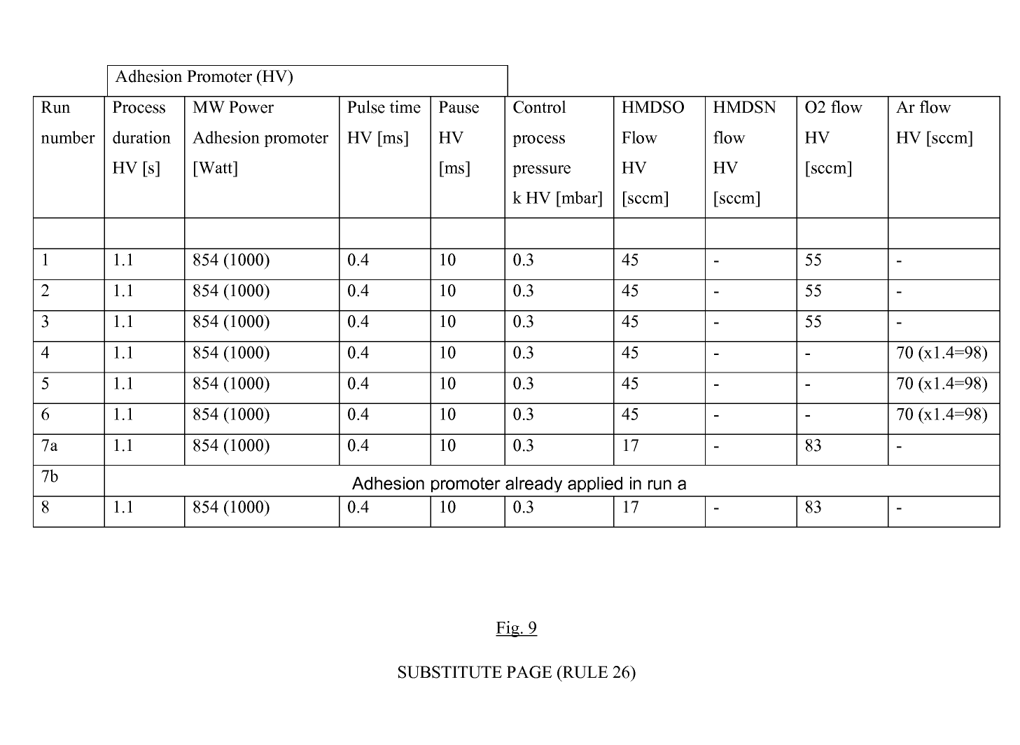

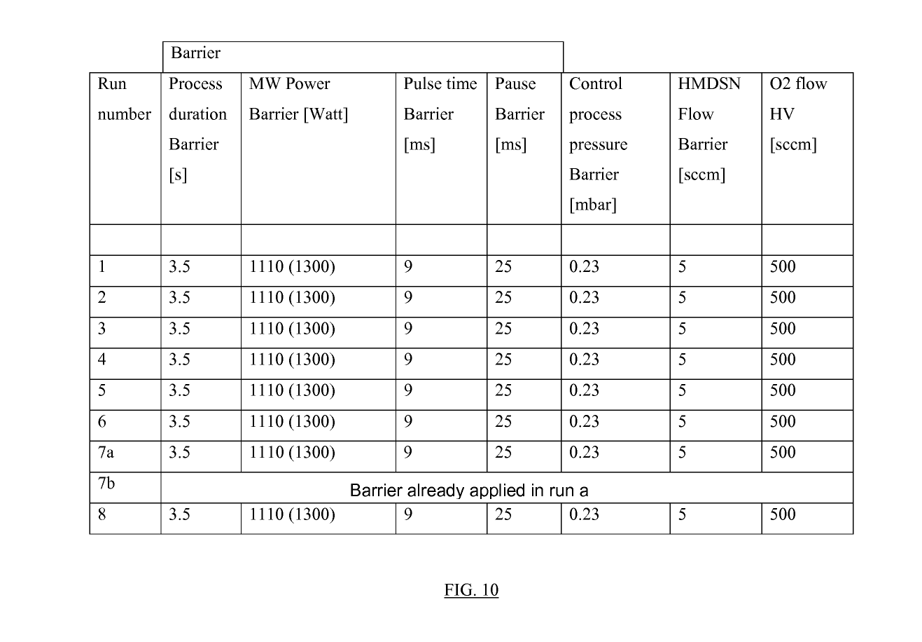

FIG. 9 shows process data for creating an adhesion promoter for the process variants of FIG. 8;

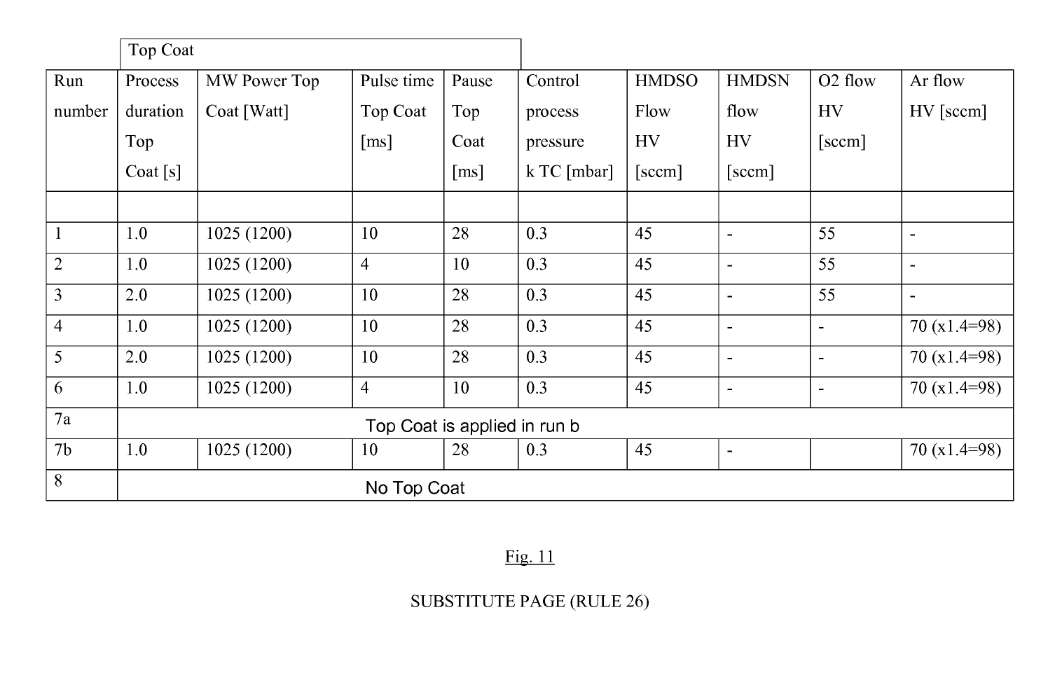

FIG. 10 shows process data for creating a barrier layer for the process variants of FIG. 8;

FIG. 11 shows process data for creating a protective layer for the process variants of FIG. 8;

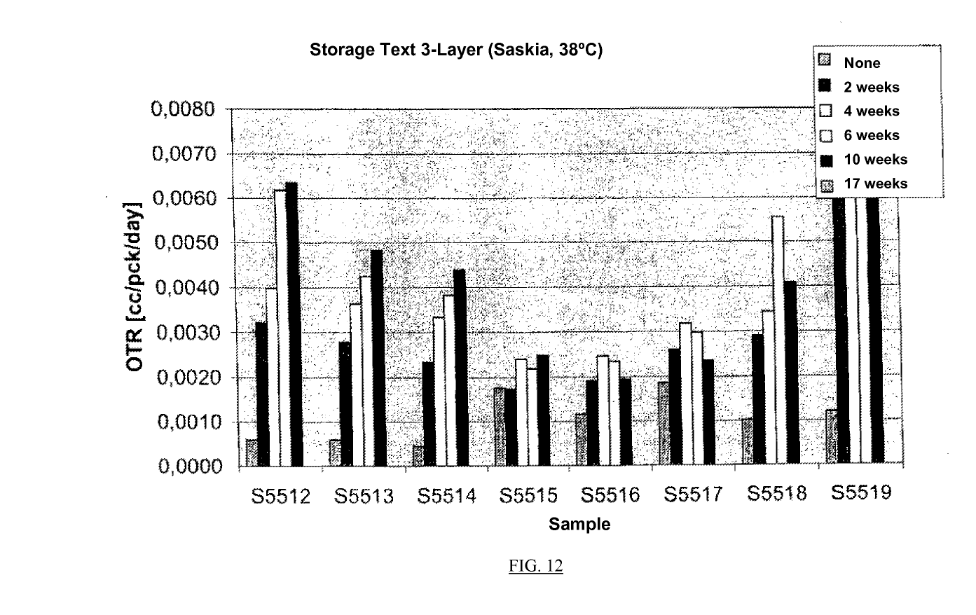

FIG. 12 shows a diagram to compare barrier properties of barrier layers, which were deposited using the differing process gas compositions of FIG. 8;

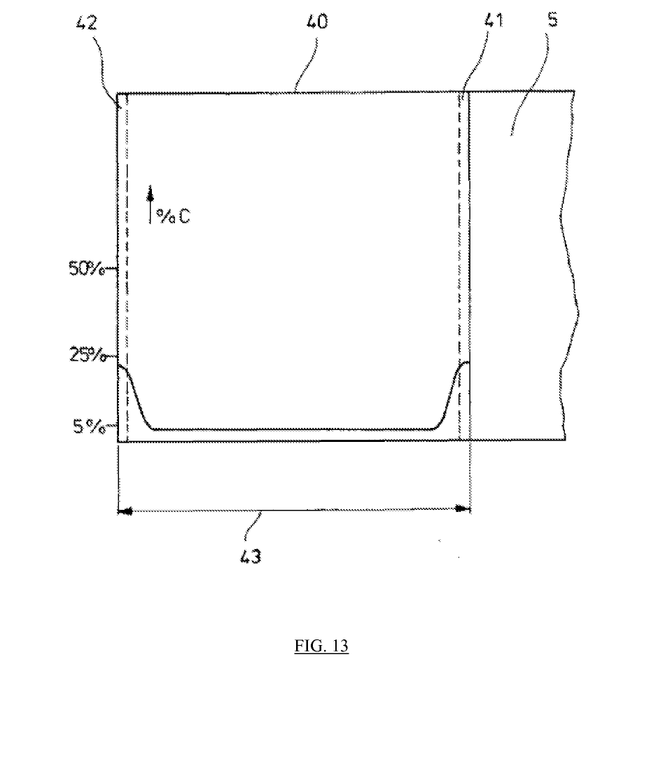

FIG. 13 shows a drastically increased cross-section through a barrier layer having a carbon content that can be varied with the layer thickness.

A plasma module (1) can be seen in the illustration of FIG. 1, which is provided with a rotating plasma wheel (2). A plurality of plasma stations (3) are disposed along a circumference of the plasma wheel (2). The plasma stations (3) are provided with cavities (4) or plasma chambers (17) for receiving workpieces (5) to be treated.

The workpieces (5) to be treated are supplied to the plasma module (1) in the region of a feed area (6) and forwarded via a separation wheel (7) to a transfer wheel (8), which is equipped with positionable support arms (9). The support arms (9) are disposed so as to pivot relative to a base (10) of the transfer wheel (8), so that a change of the distance of the workpieces (5) with respect to each other can be carried out. This results in a transfer of the workpieces (5) from the transfer wheel (8) to a feed wheel (11), with a distance of the workpieces (5) with respect to each other that is larger as compared to that on the separation wheel (7). The feed wheel (11) transfers the workpieces (5) to be treated to the plasma wheel (2). After the treatment is carried out, the treated workpieces (5) are removed from the region of the plasma wheel (2) by a discharge wheel (12) and transferred into the region of a discharge segment (13).

In the embodiment according to FIG. 2, each of the plasma stations (3) is equipped with two cavities (4) or plasma chambers (17). This allows two workpieces (5) at a time to be treated simultaneously. In general, it is possible to design the cavities (4) completely separate from each other, however it is also possible in general to only delimit sub-regions in a common cavity space from each other so that optimal coating of all workpieces (5) is assured. It is considered in particular to delimit the sub-cavities from each other at least by separate microwave incoupling areas.

FIG. 3 is a perspective illustration of a plasma module (1) comprising a partially installed plasma wheel (2). The plasma stations (3) are disposed on a support ring (14), which is designed as part of a rotary connection and mounted in the region of a machine base (15). Each of the plasma stations (3) comprises a station frame (16), which retains the plasma chambers (17). The plasma chambers (17) comprise cylindrical chamber walls (18) and microwave generators (19).

A rotary distributor (20), by way of which the plasma stations (3) are supplied with working fluids and energy, is disposed at the center of the plasma wheel (2). Especially circular lines (21) can be used to distribute the working fluids.

The workpieces (5) to be treated are shown below the cylindrical chamber walls (18). Lower parts of the plasma chambers (17) are not shown for simplicity reasons.

FIG. 4 shows a perspective illustration of a plasma station (3). It can be seen that the station frame (16) is provided with guide rods (23), on which a carriage (24) for retaining the cylindrical chamber wall (18) is guided. FIG. 4 shows the carriage (24) with the chamber wall (18) in a raised state, whereby the workpiece (5) is released.

The microwave generator (19) is disposed in the upper region of the plasma station (3). The microwave generator (19) is connected via a connector (25) and an adapter (26) to a coupling channel (27), which leads into the plasma chamber (17). In general, the microwave generator (19) can be disposed at a predefinable distance from the chamber cover (31), and thus in a larger surrounding region of the chamber cover (31), both directly in the region of the chamber cover (31) or coupled to the chamber cover (31) by way of a spacer element. The adapter (26) has the function of a transition element, and the coupling channel (27) is designed as a coaxial conductor. A quartz glass window is disposed in the region where the coupling channel (27) leads into the chamber cover (31). The connector (25) is designed as a waveguide.

The workpiece (5) is positioned by a holding element (28), which is disposed in the region of a chamber bottom (29). The chamber bottom (29) is designed as part of a chamber base (30). So as to facilitate adjustment, the chamber base (30) can be fixed in the region of the guide rods (23). Another variant consists of directly fastening the chamber base (30) to the station frame (16). In such an embodiment, it is also possible, for example, to implement the guide rods (23) in two pieces in the vertical direction.

FIG. 5 shows a front view of the plasma station (3) according to FIG. 3 in a closed state of the plasma chamber (17). The carriage (24) with the cylindrical chamber wall (18) is lowered here as compared to the position in FIG. 4, so that the chamber wall (18) has moved against the chamber bottom (29). In this positioning state, the plasma coating can be carried out.

FIG. 6 shows a vertical sectional view of the system of FIG. 5. It is apparent in particular that the coupling channel (27) leads into a chamber cover (31), which has a laterally protruding flange (32). A seal (33), upon which an inside flange (34) of the chamber wall (18) acts, is arranged in the region of the flange (32). In the lowered state of the chamber wall (18), the chamber wall (18) is thus sealed with respect to the chamber cover (31). Another seal (35) is disposed in a lower region of the chamber wall (18) so as to assure sealing with respect to the chamber bottom (29) here too.

In the position shown in FIG. 6, the chamber wall (18) encloses the cavity (4), so that both an interior space of the cavity (4) and an interior space of the workpiece (5) can be evaluated. So as to support the feeding of process gas, a hollow gas lance (36), which can be displaced into the interior space of the workpiece (5), is disposed in the region of the chamber base (30). So as to position the gas lance (36), the same is retained by a lance carriage (37), which can be positioned along the guide rods (23). A process gas channel, which in the raised position shown in FIG. 6 is coupled to a gas connection (39) of the chamber base (30), is coupled within the lance carriage (37). This arrangement avoids tube-like connecting elements on the lance carriage (37).

As an alternative to the design of the plasma station described above, however, it is also possible according to the invention to introduce the workpiece (5) into a plasma chamber (17) that is disposed immovably with respect to the associated support structure. As an alternative to the illustrated coating of the workpieces (5) with the mouths thereof in the perpendicular direction downward, it is likewise possible to carry out a coating of the workpieces with the mouths thereof perpendicularly upward. In particular it is considered to carry out a coating of bottle-shaped workpieces (5). Such bottles are likewise preferably made of a thermoplastic material. Preferably the use of PET or PP is considered. According to a further preferred embodiment, the coated bottles are used to receive beverages.

A typical treatment process will be described hereafter based on the example of a coating process and carried out so that the workpiece (5) is first transported to the plasma wheel (2) using the feed wheel (11), and the workpiece (5) is inserted into the plasma station (3) in the pushed-up state of the sleeve-like chamber wall (18). After completing the insertion process, the chamber wall (18) is lowered into the sealed position thereof, and initially both the cavity (4) and also an interior space of the workpiece (5) are evacuated.

Following sufficient evacuation of the interior space of the cavity (4), the lance (36) is retracted into the interior space of the workpiece (5), and the interior space of the workpiece (5) is separated with respect to the interior space of the cavity (4) by a displacement of the holding element (28). It is likewise possible to displace the gas lance (36) into the workpiece (5) already synchronously with the onset of the evacuation of the interior space of the cavity. Thereafter, the pressure in the interior space of the workpiece (5) is lowered further. In addition, it is also considered to carry out the positioning movement of the gas lance (36) at least partially parallel with the positioning of the chamber wall (18). After reaching a sufficiently low negative pressure, process gas is introduced into the interior space of the workpiece (5) and the plasma is ignited using the microwave generator (19). In particular it is considered to deposit both an adhesion promoter to the inner surface of the workpiece (5) and the actual barrier layer made of silicon oxides by way of the plasma.

Following a conclusion of the coating process, the gas lance (36) is again removed from the interior space of the workpiece (5), and both the plasma chamber (17) and the interior space of the workpiece (5) are ventilated. After the ambient pressure has been reached within the cavity (4), the chamber wall (18) is raised again so as to remove the coated workpiece (5) and feed a new workpiece (5) to be coated.

The chamber wall (18), the sealing element (28) and/or the gas lance (36) can be positioned using different drive units. In principle, the use of pneumatic drives and/or electric drives, in particular in one embodiment of the linear motor, is conceivable. However, it is considered in particular to implement a cam control unit so as to support an exact coordination of movement with a rotation of the plasma wheel (2). For example, the cam control unit can be implemented such that radial cams along, which cam rollers are guided, are disposed along a circumference of the plasma wheel (2). The cam rollers are coupled to the respective components to the positioned.

FIG. 7 shows a partial illustration of an enlarged cross-section through a workpiece (5), which is provided with a barrier layer (40). The barrier layer (40) is typically disposed on a wall of a bottle-shaped container. The workpiece (5) is in particular made of PET. The barrier layer (40) is preferably connected to the workpiece (5) by way of an adhesive layer (41). In addition, it is possible to provide the barrier layer (40) with a protective layer (42) in the region of the extension of the layer facing away from the workpiece (5).

In general, the adhesive layer (41) and/or the protective layer (42) can be designed as layers that are delimited from the barrier layer (40), however in particular it is considered to implement what are known as gradient layers, in which a layer-like effect is achieved by varying the elemental composition with a layer thickness (43). This provides what are known as gradient layers. The change of the elemental composition affects at least one of the chemical elements that are carbon, silicon and oxygen. However, in principle other chemical elements can be used in addition or as an alternative.

FIG. 8 shows different process parameters for eight different samples. A process is carried out for sample numbers S 5512 to S 5514, in which both the adhesive layer (41) as well as the barrier layer (40) and the protective layer (42) are deposited in the presence of oxygen as the process gas. Both the adhesive layer (41) and the protective layer (42) are deposited in the presence of argon for sample numbers S 5514 to S 5517. The deposition of the adhesive layer (41) for sample number S 5518 is carried out in the presence of oxygen and the deposition of the protective layer (42) is carried out in the presence of argon. The deposition of the adhesive layer (41) for sample number S 5519 is carried out in the presence of oxygen and no protective layer (42) is applied.

In each case bottles are produced, which are suitable for being filled with a hot substance.

FIG. 9 shows the process parameters for applying the adhesive layer (41) to the sample numbers according to FIG. 8. The pulse times here refer to the pulse width of the ignited microwave pulses and the pauses refer to the intervals between the individual microwave pulses. Also entered are the microwave power and the applied process pressure. The flow for HMDSO and those for oxygen or argon are also listed.

Similarly, FIG. 10 is a tabular compilation of the process parameters for applying the barrier layer (40), and FIG. 11 is a compilation of the process parameters for applying the protective layer (42).

FIG. 12 shows the barrier properties of the samples according to FIG. 8 in the form of a bar chart. In general, it can be seen that the barrier properties decrease as the storage time increases. In addition, it is apparent that the barrier properties are considerably better when depositing the protective layer (42) in the presence of argon than the barrier properties when depositing the protective layer (42) in the presence of oxygen. In particular, it has been proven advantageous to deposit both the adhesive layer (41) and the protective layer (42) in the presence of argon.

FIG. 13 shows another enlarged partial cross-section through a workpiece (5) comprising a barrier layer (40). In addition, a curve of the carbon concentration is plotted over the layer thickness (43) in percent.

The functional properties of the adhesive layer (41) and/or of the protective layer (42) are achieved by varying the elemental composition. The carbon content in percent in the region of the functional adhesive layer (41) and/or of the functional protective layer (42) typically ranges from 10 to 60 percent. A value of approximately 30 to 60 percent is preferred for the protective layer (42). The carbon content in the region of the functional barrier properties is approximately 5 percent.

According to a preferred embodiment of the method according to the invention, a silicon-containing gas and argon, but not oxygen, are supplied so as to create the adhesive layer (41). The silicon-containing gas and oxygen, but not argon, are supplied so as to create the barrier layer (40). The silicon-containing gas and argon, but not oxygen, are again supplied so as to create the protective layer (42).

In all the exemplary embodiments described above, it is in particular also considered to use at least one additional noble gas in addition to the argon, or to substitute the argon with at least one other noble gas.

1. A method for the plasma treatment of a workpiece, in which the workpiece is inserted into a plasma chamber and thereafter, under the action of a negative pressure, a coating is deposited on the workpiece after a plasma is ignited, and in which the plasma is ignited by microwave energy, the coating being composed at least of a gas barrier layer and a protective layer, and the gas barrier layer comprising SiOx and the protective layer comprising carbon, wherein the protective layer is produced from a gas comprising at least one silicon compound and argon.

2. The method according to claim 1, wherein hexamethyldisiloxane is used as a process gas.

3. The method according to claim 1, wherein hexamethyldisilazane is used as a process gas.

4. The method according to claim 1, wherein pulsed microwaves are used to ignite the plasma.

5. The method according to claim 1, wherein process gases are supplied in a substantially constant volume flow over the duration of the creation of the protective layer.

6. The method according to claim 1, wherein carbon is deposited in a content of approximately 30 to 60 elemental percent in the protective layer.

7. The method according to claim 1, wherein an adhesion promoting layer is created between the workpiece and the barrier layer.

8. The method according to claim 1, wherein at least one further noble gas is used, in addition to the argon.

9. The method according to claim 1, wherein no oxygen is supplied as process gas when the protective layer is created.

10. The method according to claim 7, wherein no oxygen is supplied as process gas when the adhesive layer is created.

11. The method according to claim 1, wherein no argon is supplied as process gas when the barrier layer is created.

12. A workpiece made of a thermoplastic material, which in a region of at least one surface is provided with a gas barrier layer that is deposited from plasma and includes SiOx, and in which a protective layer comprising carbon is disposed on the gas barrier layer, wherein the protective layer includes argon.

13. The workpiece according to claim 12, wherein an adhesion promoting layer is disposed between the workpiece and the gas barrier layer.

14. The workpiece according to claim 12, wherein the workpiece is a bottle and is provided with the gas barrier layer on an inner surface.

15. The workpiece according to claim 13, wherein the adhesion promoting layer includes argon.
